(19) United States
(12) Patent Application Publication
(10) Pub. No.: US 2009/0201474 A1
(43) Pub. Date: Aug. 13, 2009

(54) Semiconductor Devices and Methods of Manufacture Thereof

(76) Inventor: Sajan Marokkey, Wappingers Falls, NY (US)

Correspondence Address: SLATER & MATSIL LLP, 17950 PRESTON ROAD, SUITE 1000, DALLAS, TX, 75252, US

(21) Appl. No.: 12/030,790

(22) Filed: Feb. 13, 2008

(51) Int. Cl. G03B 27/42; G03F 7/00; G03F 1/00

(52) U.S. Cl. 355/53; 430/313; 430/5; 428/195.1

(57) ABSTRACT

Methods of manufacturing semiconductor devices, structures thereof, methods of fabricating lithography masks, and lithography masks and systems are disclosed. In one embodiment, a method of manufacturing a semiconductor device includes providing a workpiece, the workpiece comprising a first thickness in a first region and at least one second thickness in at least one second region. A layer of photosensitive material is disposed over the workpiece, and a lithography mask is provided. The lithography mask has a first phase shift in a first region and at least one second phase shift in at least one second region. The layer of photosensitive material is exposed to energy through the lithography mask, and the layer of photosensitive material is developed, leaving portions of the workpiece exposed. The exposed portions of the workpiece are affected using the layer of photosensitive material as a mask.

### TECHNICAL FIELD

The present invention relates generally to the fabrication of semiconductor devices, and more particularly to the patterning of material layers of semiconductor devices.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various material layers using lithography to form circuit components and elements thereon, forming an integrated circuit.

One type of semiconductor lithography involves positioning a patterned mask between a semiconductor workpiece and an energy source to expose portions of a photosensitive material deposited on the workpiece, transferring the mask pattern to the photosensitive material. The photosensitive material is then developed and used as a mask while exposed regions of a material on the workpiece are etched away. The photosensitive material is removed, and additional material layers may be deposited and patterned in a similar fashion. There may be a dozen or more lithography mask levels required to manufacture an integrated circuit, for example.

As semiconductor devices are scaled down or reduced in size, lithography of semiconductor devices becomes more difficult. Planarization of isolated features and nested features may result in uneven topography of a top surface of a semiconductor wafer, which may deleteriously affect lithography processes.

Therefore, what are needed in the art are improved methods of manufacturing semiconductor devices.

### SUMMARY OF THE INVENTION

These and other problems are generally solved or circumvented, and technical advantages are generally achieved, by preferred embodiments of the present invention, which provide novel methods and lithography masks for patterning material layers of semiconductor devices.

In accordance with an embodiment of the present invention, a method of manufacturing a semiconductor device includes providing a workpiece, the workpiece comprising a first thickness in a first region and at least one second thickness in at least one second region. A layer of photosensitive material is disposed over the workpiece, and a lithography mask is provided. The lithography mask has a first phase shift in a first region and at least one second phase shift in at least one second region. The layer of photosensitive material is exposed to energy through the lithography mask, and the layer of photosensitive material is developed, leaving portions of the workpiece exposed. The exposed portions of the workpiece are affected using the layer of photosensitive material as a mask.

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention and the advantages thereof, reference is now made to the following descriptions taken in conjunction with the accompanying drawings, in which:

FIGS. 1 and 2 show cross-sectional views of a semiconductor device comprising nested and isolated features formed in a first insulating material using a damascene process that comprise different heights over a surface of a workpiece, creating an uneven topography on the top surface of the material layer;

FIG. 3 shows the semiconductor device of FIG. 2 after a second insulating material and a layer of photosensitive material have been formed over the nested and isolated features within the first insulating material, wherein a lithography mask comprising a first phase shift Φ₁ in a first region and a second phase shift Φ₂ in a second region is used to pattern the layer of photosensitive material in accordance with embodiments of the present invention;

FIG. 4 illustrates a cross-sectional view of a lithography mask in accordance with an embodiment of the present invention wherein a thickness of an attenuated phase shifting material is varied in different regions of the mask to create different phase shifts;

FIG. 5 illustrates a cross-sectional view of an embodiment of the present invention wherein a thickness of a substrate of a lithography mask is varied in different regions of the mask to create different phase shifts;

FIGS. 6 through 10 show cross-sectional views of a method of manufacturing a semiconductor device having an uneven topography in accordance with embodiments of the present invention using the lithography mask shown in FIG. 4 or 5 and using a damascene process;

FIG. 11 shows a top view of a semiconductor device shown in FIG. 10 that has been patterned using a dual damascene process, simultaneously forming conductive lines and vias within an insulating material;

FIG. 12 is a graph illustrating effects of phase shift difference on focus in regions of the lithography mask having different phase shifts; and

FIG. 13 is a plot illustrating differences in focus created by the different phase shifts in regions of the lithography mask.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

Metallization layers are usually the top-most material layers of semiconductor devices. The manufacturing of semiconductor devices is typically classified into two phases, a front end of line (FEOL) and a back end of line (BEOL). The BEOL is typically considered to be the point of the manufacturing process where metallization layers are formed, and the FEOL is generally considered to include the manufacturing processes prior to the formation of the metallization layers.

While some integrated circuits have a single top layer of metallization, other integrated circuits comprise multi-level interconnects, wherein two or more metallization layers are formed over a semiconductor wafer or workpiece. Each conductive line layer typically comprises a plurality of conductive lines separated from one another by an insulating material, also often referred to as an inter-level dielectric (ILD). The conductive lines in adjacent horizontal metallization layers may be connected vertically in predetermined places by vias formed between the conductive lines. The first metallization layer in a multi-level interconnect scheme is often referred to as a contact layer, for example.

Damascene processes may be used to form conductive features in metallization layers, e.g., particularly if the conductive features comprise copper, which is a material that is difficult to subtractively etch. In a damascene process, a material such as a dielectric or insulator is deposited over a wafer, and then the material is patterned with a conductive feature pattern. The conductive feature pattern typically comprises a plurality of trenches (for conductive lines), or apertures (for vias), for example. The trenches or apertures are then filled in with a conductive material, and a chemical-mechanical polish (CMP) process and/or etch process is used to remove the excess conductive material from the top surface of the patterned material. The conductive material remaining within the patterned material comprises conductive features such as conductive lines and/or vias.

Damascene processes are typically either single or dual damascene. In a single damascene process, one metallization layer is formed at a time. In a dual damascene process, two adjacent horizontal metallization layers are patterned, e.g., by forming two lithography patterns in two insulating material layers such as dielectric layers or in a single insulating material layer. The two patterns are then filled in with conductive material, and a CMP process is used to remove excess conductive material from over the insulating material, leaving patterned conductive material in the insulating material layers. For example, the patterns may comprise trenches for conductive lines in one insulating material layer portion and apertures for vias in the underlying insulating material layer portion. Thus, in a dual damascene process, conductive line trench patterns and via aperture patterns are filled in one fill step.

After a CMP polish in a damascene process, topography differences may be caused by underlying feature or circuit density differences. The top surface of material layers after a CMP process may not be planar, but rather, may comprise an uneven topography. Feature pattern density affects the result of a CMP process: isolated features may be reduced in height from the CMP process in comparison to closely nested features, for example. When additional material layers are deposited over the features having different heights, the material layers are thinner over the reduced in height isolated features than over the nested features, which can cause focus problems in subsequent lithography processes.

In BEOL lithography process, topography differences between various regions on a chip may consume a large portion of a focus budget for a material layer. Planarizing coatings used before the masking step, e.g., before a layer of photoresist is applied, may not correct topography differences. Topography differences across regions of a semiconductor device may vary by about 100 nm or greater in some applications, which may result in undesired exposure results. The varying height of the topography may result in a single best focus level being inadequate for exposure across an entire wafer, for example.

Thus, improved methods of patterning material layers of semiconductor devices are needed in the art.

The present invention will be described with respect to preferred embodiments in a specific context, namely, in methods of manufacturing semiconductor devices having uneven topographies. Embodiments of the invention may also be applied, however, to other applications that require patterning of materials having uneven topographies, for example.

Embodiments of the present invention provide novel methods of manufacturing semiconductor devices, and semiconductor devices manufactured using the novel methods. Embodiments of the present invention also include novel lithography masks and methods of manufacture thereof, and lithography systems including the lithography masks, to be described further herein.

Embodiments of the present invention will be described with respect to methods of manufacturing semiconductor devices, namely in the patterning of contacts, vias, or other conductive features of semiconductor devices using damascene processes. Embodiments of the present invention may also be used to form features comprising other materials, such as semiconductive or insulating materials, or other materials combined with these material and conductive materials. Embodiments of the invention may be implemented in semiconductor applications such as transistors, memory devices, logic devices, mixed signal devices, and other applications, as examples.

Methods of focus compensation in lithography masks for semiconductor devices with material layers having an uneven topography will be described herein. The novel methods compensate for focus requirement differences between regions of a semiconductor device having different topographies. The compensation of the uneven topography is achieved by tuning the phase of the lithography mask proximate the patterns for features that will be formed in the material layer, based on the topography in various regions of the material layer on the semiconductor device. Embodiments of the present invention utilize an effect of focus difference created by a phase shift of an attenuated phase shifting mask to compensate for topography differences of a semiconductor device, to be described further herein.

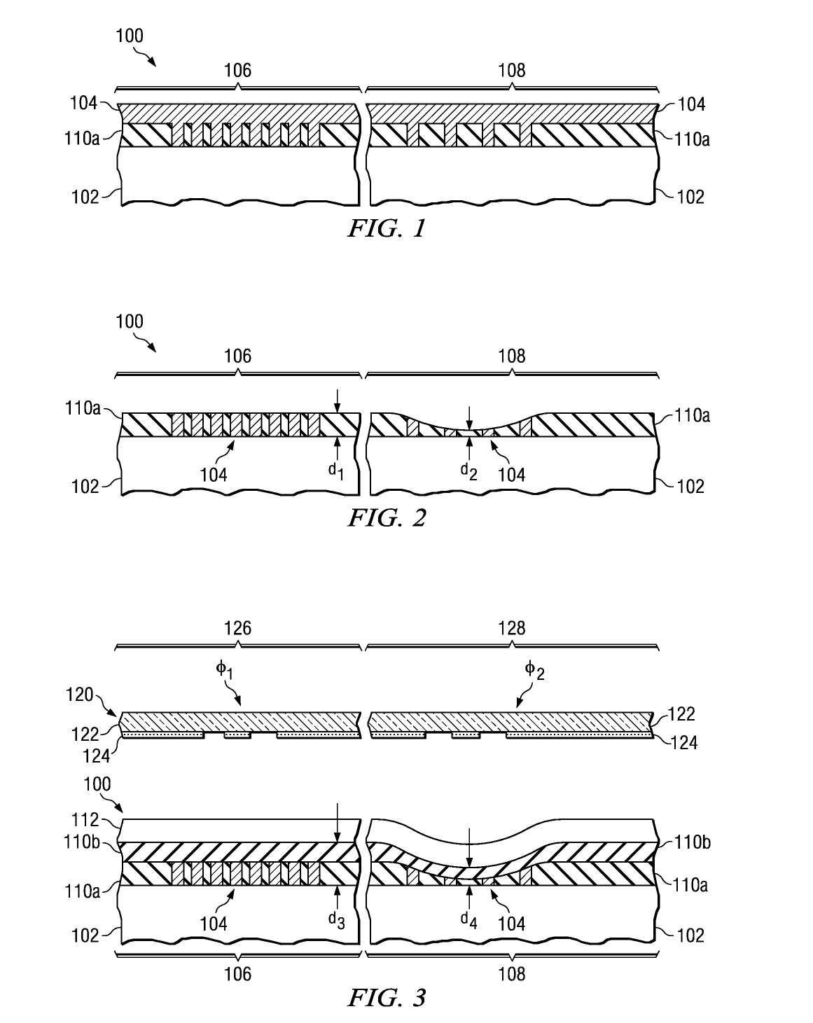

With reference now to FIG. 1, a semiconductor device 100 is shown comprising a workpiece or wafer 102. A cross-sectional view of the semiconductor device 100 is shown. A damascene process is used to form features over the workpiece 102. To form the features, a first insulating material 110a is formed over the workpiece 102, and the first insulating material 110a is patterned with a pattern for nested features in a first region 106 and a pattern for isolated features in a second region 108. A conductive material 104 is formed over the patterned first insulating material 110a, as shown in FIG. 1, filling the patterns in the first insulating material 110a.

A chemical-mechanical polish (CMP) process is used to planarize the workpiece 102 and remove the conductive material 104 from over the top surface of the first insulating material 110a, leaving features 104 formed within the first insulating material 110a, as shown in FIG. 2. Nested and isolated features 104 are formed in regions 106 and 108, respectively, which comprise different heights over a surface of a workpiece 102. The CMP process results in features 104 in the first region 106 that are closely nested being taller and having a greater height than features 104 in the second region 108 that are isolated, which have been reduced in height during the CMP process compared to the nested features in the first region 106. Features 104 in the first region 106 may comprise a height or dimension d₁ that is greater than the height or dimension d₂ of features 104 in the second region 108, as shown. The features 104 may comprise conductive features such as conductive lines that run in and out of the page, or the features 104 may comprise vias, for example.

FIG. 3 shows the semiconductor device 100 shown in FIG. 2 after a second insulating material 110b is formed over the nested and isolated features 104 formed in the first insulating material 110a. The underlying patterns of the features 104 have an effect on the topography of the top surface of the second insulating material 110b, as shown. The height or dimension d₃ of the second insulating material 110b in region 106 may be greater than the height or dimension d₄ of the second insulating material 110b in region 108, as shown. The difference in the heights d₁ and d₂ of the high density nested features 104 in the first region 106 and the low density isolated features 104 in the second region 108, respectively, within the first insulating material 110a underlying the second insulating material 110b cause an uneven topography of the second insulating material 110b. The thickness, e.g., dimension d₄ of the first insulating material 110a is thinner proximate the isolated features 104 in region 108 than proximate the nested features 104 in region 106 having a dimension d₃, creating an uneven topography on the top surface of the second insulating material 110b. The uneven topography of the second insulating material 110b creates a different best focus setting for the second insulating material 110b in region 106 than in region 108.

To pattern the second insulating material 110b, a layer of photosensitive material 112 is formed over the second insulating material 110b, as shown in FIG. 3. The layer of photosensitive material 112 may comprise a photoresist, and is substantially conformal as deposited, as shown. Thus, the uneven topography of the second insulating material 110b is transferred to the topography of the layer of photosensitive material 112. The uneven topography of the layer of photosensitive material 112 is substantially the same as the uneven topography of the second insulating material 110b, for example.

To optimize lithography processes, a top surface of a semiconductor device is required to be planar, in order for features to print as desired across the surface of the semiconductor device. However, in accordance with embodiments of the present invention, features may accurately be printed across a semiconductor device 100 such as the one shown in FIG. 3 having an uneven topography. A novel lithography mask 120 comprising a first phase shift Φ₁ in a first region 126 and a second phase shift Φ₂ in a second region 128 is provided and used to pattern the layer of photosensitive material 112 of the semiconductor device 100, creating different focus levels in the various regions 106 and 108 of the device 100 to compensate for the uneven topography.

Only one first region 106 and one second region 108 are shown in the drawings; however, the semiconductor device 100 (and/or the workpiece 102 or a material layer disposed over the workpiece 102) may comprise a plurality of first regions 106 and a plurality of second regions 108, for example, not shown. The second region 108 of the semiconductor device 100 is also referred to herein as at least one second region 108, for example. The second region 108 may comprise a plurality of regions, with each of the plurality of regions having a different thickness or height, for example.

Likewise, the lithography mask 120 may comprise a plurality of first regions 126 and a plurality of second regions 128, also not shown. The second region 128 of the lithography mask 120 is also referred to herein as at least one second region 128, for example. The second region 128 may comprise a plurality of regions, with each of the plurality of regions having a different phase shift to compensate for the different thicknesses or heights of the second regions 108 of the semiconductor device 100, for example.

The first region of the lithography mask 120 may correspond with the first region of the semiconductor device 100. The first region of the lithography mask 120 may be used to pattern the first region of the semiconductor device 100, for example.

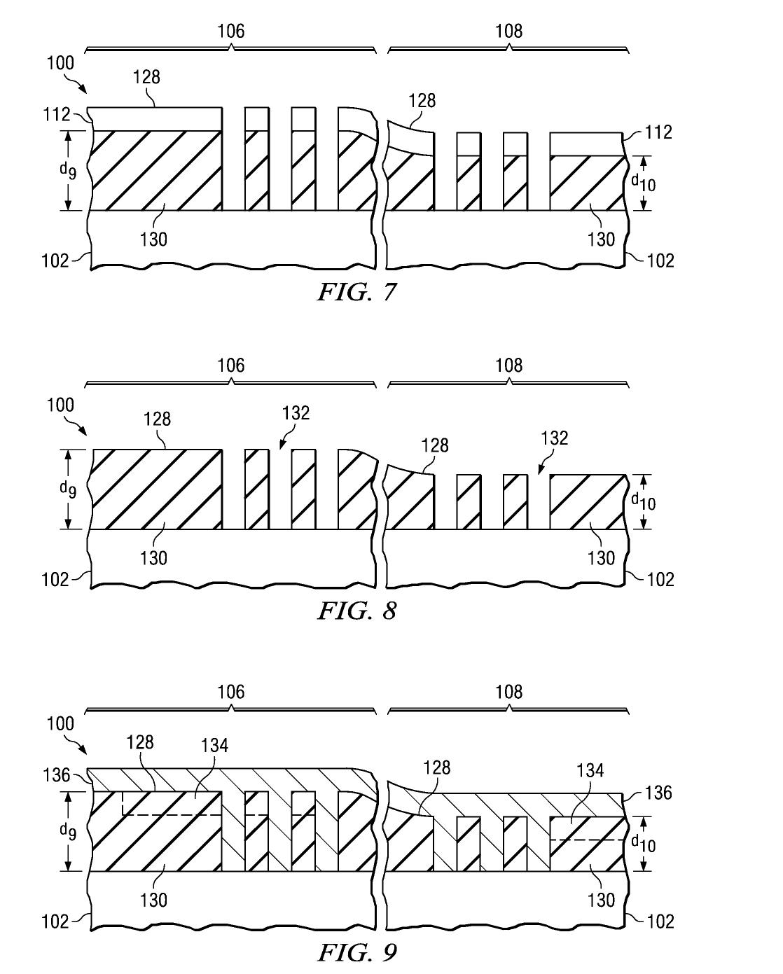

After providing the novel lithography mask 120 comprising a first phase shift Φ₁ in the first region 106 and at least one second phase shift Φ₂ in the at least one second region 128, the layer of photosensitive material 112 is exposed to energy through the lithography mask 120. The layer of photosensitive material 112 is developed, leaving portions of the workpiece 102 exposed (not shown in FIG. 3; see FIG. 7). The exposed portions of the workpiece 102 (e.g., such as second insulating material 110b and optionally also features 104 and/or portions of the workpiece 102 itself) are affected using the layer of photosensitive material 112 as a mask.

In some embodiments, affecting the portions of the workpiece 102 may comprise etching away the exposed portions of the workpiece 102, (e.g., second insulating material 110b) which will be described further herein with reference to the embodiment shown in FIGS. 6 through 8. Alternatively, affecting the exposed portions of the workpiece 102 may comprise implanting a substance into the exposed portions of the workpiece 102, or forming, depositing, or growing a material on the exposed portions of the workpiece 102, as examples, although alternatively, the workpiece 102 may be altered or affected in other ways.

Next, the lithography mask 120 shown in FIG. 3 of embodiments of the present invention will be described. The novel lithography mask 120 includes a substrate 122 and an attenuated phase shifting material 124 disposed over the substrate 122. The substrate 122 may comprise a substantially transparent material such as quartz or glass, and may comprise a thickness of about 500 μm, for example. Alternatively, the substrate 122 may comprise other dimensions.

The attenuated phase shifting material 124 may comprise a partially transmissive material such as MoSi, although other attenuating materials may also be used for the attenuated phase shifting material 124. The attenuated phase shifting material 124 may comprise a thickness of about 100 nm, or about 300 nm or less, as examples, although the attenuated phase shifting material 124 may alternatively comprise other dimensions.

The attenuated phase shifting material 124 comprises patterns in the first region 126 and the at least one second region 128 of the lithography mask 120, as shown. The patterns may comprise a pattern for a plurality of vias or other features of the semiconductor device 100, for example. The patterns in the attenuated phase shifting material 124 will be used to pattern the layer of photosensitive material 112, which may be used as a mask to form features on the semiconductor device 100 or to alter the semiconductor device 100 in the shape of the patterns.

The patterns for the features in the first region 126 of the mask 120 and the at least one second region 128 preferably comprise the same size or dimensions in some embodiments, for example. Alternatively, the patterns for the features in the first region 126 and the at least one second region 128 may comprise different sizes and dimensions.

The lithography mask 120 comprises a first phase shift Φ₁ in the first region 126 and at least one second phase shift Φ₂ in the at least one second region 128. The different phase shifts Φ₁ and Φ₂ in regions 126 and 128 of the mask 120 cause different focus levels to be emitted from the lithography mask 120 when it is used during an exposure process of a semiconductor device 100. Thus, the lithography mask 120 advantageously provides a means of tuning the focus levels for different regions 106 and 108 of the semiconductor device 100, providing the ability to expose a semiconductor device at a variety of focus levels in a single exposure process.

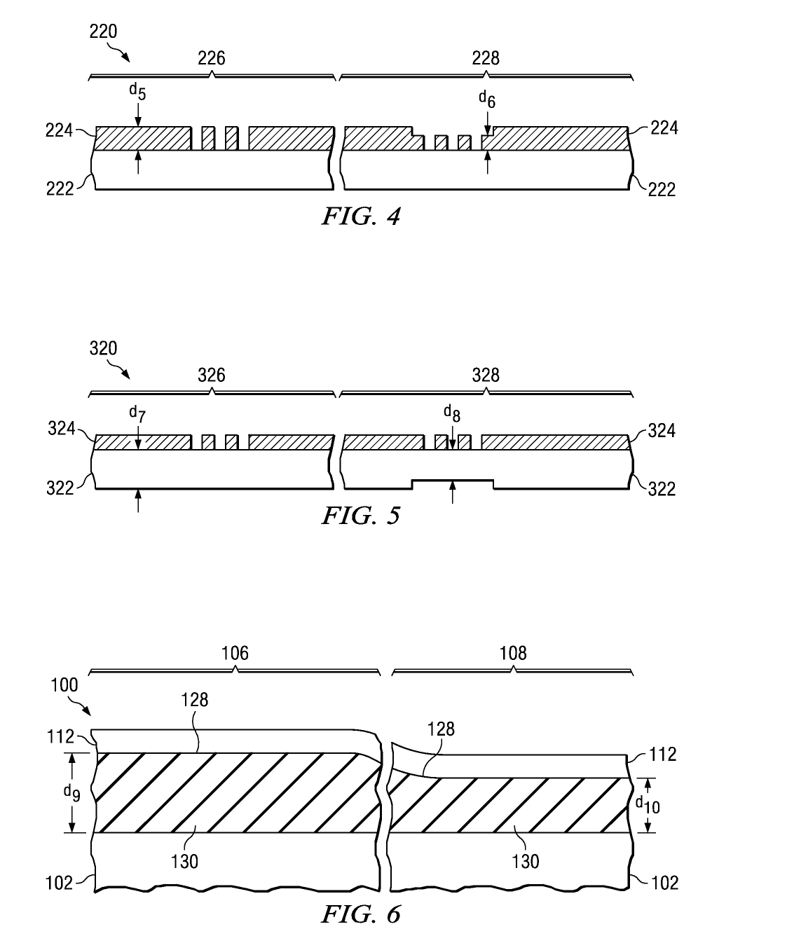

The phase shifts Φ₁ and Φ₂ in the first region 126 and the at least one second region 128 of the lithography mask 120 may be achieved by varying the thickness of the substrate 122, as shown in FIG. 5 at 322, by varying the thickness of the attenuated phase shifting material 124, as shown in FIG. 4 at 224, or by varying the thicknesses of both the substrate 122 and the attenuated phase shifting material 124. After the manufacturing process for the lithography mask 120, for example, portions of the substrate 122 or attenuating phase shifting material 124 may be patterned and etched to create the various phase shifts Φ₁ and Φ₂ in the various regions 126 and 128 of the mask 120.

Alternatively, the phase shifts Φ₁ and Φ₂ in the first region 126 and/or the at least one second region 128 of the lithography mask 120 may be achieved by modifying the refractive index of the substrate 122 and/or the attenuated phase shifting material 124 proximate the patterns in the first region 126 and the at least one second region 128. For example, the substrate 122 or the attenuated phase shifting material 124 of the lithography mask 120 may be implanted with ions or atoms of a substance, such as potassium, although other substances may also be used, to modify the optical characteristics of the mask 120 in the desired area. The attenuated phase shifting material 124 or the substrate 122, or both the attenuated phase shifting material 124 and the substrate 122 may include an implanted substance adapted to produce the first phase shift or the at least one second phase shift of the lithography mask 120, for example.

The phase shifts Φ₁ and Φ₂ in regions 126 and 128 are intentionally varied in accordance with embodiments of the present invention, to provide custom focus levels for regions 106 and 108 of the workpiece 102, providing improved lithography processes, wherein optimal focus levels are achievable for different regions 106 and 108 of the semiconductor device 100.

For example, FIG. 4 illustrates a cross-sectional view of a lithography mask 220 in accordance with an embodiment of the present invention wherein a thickness of an attenuated phase shifting material 224 is varied in different regions 226 and 228 of the mask 220 to create different phase shifts. Like numerals are used for the various elements that were used to describe FIG. 3. To avoid repetition, each reference number shown in FIG. 4 is not described again in detail herein. Rather, similar materials are preferably used for the various material layers and regions x20, x22, x24, etc. . . . shown as were used to describe FIG. 3, where x=1 in FIG. 3 and x=2 in FIG. 4. As an example, the preferred and alternative materials and dimensions described for the attenuated phase shifting material 124 shown in FIG. 3 are preferably also used for the attenuated phase shifting material 224 shown in FIG. 4.

For example, in FIG. 4, an embodiment of the present invention is shown wherein the thickness of the attenuated phase shifting material 224 varies in regions 226 and 228. The thickness of the attenuated phase shifting material 224 in region 226 may comprise a dimension d₅ that is greater than the thickness of the attenuated phase shifting material 224 in region 228 comprising dimension d₆. Dimension d₅ is also referred to herein as a first thickness, and dimension d₆ is also referred to herein as at least one second thickness of the attenuated phase shifting material 224, for example. The dimensions d₅ and d₆ may vary by about 50 nm or less, or by about 300 nm or less in some embodiments, for example, depending on the amount of phase shifts Φ₁ and Φ₂ desired.

The thicknesses of the attenuated phase shifting material 224 in regions 226 and 228 may comprise dimensions d₅ and d₆ such that an amount of phase shifts Φ₁ and Φ₂ in the first region 226 and the at least one second region 228 comprise a desired focus level depending on the topography of the semiconductor device 100 in the first region 106 and the second region 108. The amount of the phase shifts Φ₁ and Φ₂ in regions 226 and 228 of the lithography mask 220 is also referred to herein as a background phase shift of the regions 226 and 228 of the lithography mask 220, for example.

The first thickness comprising dimension d₅ and the at least one second thickness comprising dimension d₆ of the attenuated phase shifting material 224 may be determined using Equation 1 in some embodiments:

$$T / P S = \frac{λ}{n * 360} ; \qquad Eq . 1$$

wherein T comprises the first thickness d₅ or the at least one second thickness d₆, wherein PS is the amount of the phase shift Φ₁ or Φ₂ in the first region 226 or the at least one second region 228 in degrees, wherein λ comprises a wavelength of an exposure process used to pattern a photosensitive material of a semiconductor device 100 (e.g., the layer of photosensitive material 112 shown in FIG. 3) using the lithography mask 220, and wherein n comprises a refractive index of the attenuated phase shifting material 224, for example.

In the embodiment shown in FIG. 4, varying the thickness of the attenuated phase shifting material 224 may result in a change in the transmissivity of the attenuated phase shifting material 224 in some regions 226 or 228. If the transmissivity of the attenuated phase shifting material 224 is sensitive to a via or feature size printed, via or feature size biasing in some regions 226 or 228 of the lithography mask 220 may be used. For example, the size of the patterns in the attenuated phase shifting material 224 may be altered to compensate for the altered transmissivity, so that the altered transmissivity of the attenuated phase shifting material 224 does not deleteriously affect the patterning of the semiconductor device 100, e.g., by affecting the focus level and/or dose of the exposure process. Thus, in these embodiments, the patterns for the features in the first region 226 and the at least one second region 228 may comprise different sizes and dimensions, for example.

FIG. 5 illustrates a cross-sectional view of a lithography mask 320 in accordance with an embodiment of the present invention, wherein a thickness of the substrate 322 of the lithography mask 320 is varied in different regions 326 and 328 of the mask 320 to create different phase shifts Φ₁ and Φ₂. Like numerals are used for the various elements that were used to describe the previous figures, and to avoid repetition, each reference number shown in FIG. 5 is not described again in detail herein.

In this embodiment, the phase shifts Φ₁ and Φ₂ in regions 326 and 328 of the lithography mask 320 are created by varying the thickness of the substrate 322 of the mask 320. For example, in FIG. 5, the thickness of the substrate 322 in region 326 may comprise a dimension d₇ that is greater than the thickness of the substrate 322 in region 328 comprising dimension d₈. The dimensions d₇ and d₈ may vary by about 100 nm or less, or by about 500 nm or less in some embodiments, for example, depending on the amount of phase shifts Φ₁ and Φ₂ desired to achieve the optimal focus level for regions 106 and 108 of the semiconductor device 100.

A method of manufacturing a semiconductor device 100 in accordance with an embodiment of the present invention will next be described. FIGS. 6 through 10 show cross-sectional views of a method of manufacturing a semiconductor device 100 having an uneven topography in accordance with embodiments of the present invention using the lithography mask 220 or 320 shown in FIG. 4 or 5, in a damascene process.

Referring next to FIG. 6, to manufacture the semiconductor device 100, first, a workpiece 102 is provided, as shown in a cross-sectional view. The workpiece 102 may include a semiconductor substrate comprising silicon or other semiconductor materials covered by an insulating layer, for example. The workpiece 102 may also include other active components or circuits, not shown. The workpiece 102 may comprise silicon oxide over single-crystal silicon, for example. The workpiece 102 may include other conductive layers or other semiconductor elements, e.g., transistors, diodes, etc. Compound semiconductors, GaAs, InP, Si/Ge, or SiC, as examples, may be used in place of silicon. The workpiece 102 may comprise a silicon-on-insulator (SOI) substrate.

The workpiece 102 comprises a material layer 130 to be patterned disposed thereon, as shown, wherein the material layer 130 has an uneven topography (e.g., which may be formed as described for the embodiment shown in FIGS. 1 through 3 by a CMP process of nested and isolated features, or by other previous manufacturing processes). The material layer 130 has a greater thickness or dimension d₉ in the first region 106 of the workpiece 102 than in the at least one second region 108 of the workpiece 102 having a thickness or dimension d₁₀. The top surface 128 of the material layer 130 in the first region 106 extends away from and above the relatively planar workpiece 102 by a greater amount than the top surface 128 of the material layer 130 in the at least one second region 108 extends above the planar workpiece 102, as shown.

The material layer 130 comprises an insulating material layer in the embodiment shown in FIGS. 6 through 11. Alternatively, the material layer 130 may comprise an insulating material, a conductive material, a semiconductive material, or multiple layers or combinations thereof. The material layer 130 is also referred to herein as a first material layer 130.

Next, a layer of photosensitive material 112 is formed over the workpiece 102, e.g., over the material layer 130, as shown. The layer of photosensitive material 112 may comprise a photoresist such as a negative or positive photoresist, for example. An optional anti-reflective coating may be formed on the workpiece 102 before the layer of photosensitive material 112 is deposited, not shown. The layer of photosensitive material 112 may be conformal, having substantially the same or similar uneven topography as the material layer 130.

Referring next to FIG. 7, the layer of photosensitive material 112 is patterned by providing a lithography mask such as mask 120, 220, or mask 320 shown in FIGS. 3, 4, and 5, respectively (not shown in FIG. 7). The lithography masks 120, 220, or 320 include regions 126 and 128, 226 and 228, or 326 and 328, respectively, having different phase shifts, which regions 126 and 128, 226 and 228, or 326 and 328 are used to pattern the regions 106 and 108, respectively, of the semiconductor device 100 shown in FIG. 7.

A lithography system is used to expose the layer of photosensitive material 112 over the workpiece 102 and the first material layer 130 to energy (e.g., such as light or energy) through the lithography mask 120 shown in FIG. 3 (or masks 220 or 320 shown in FIGS. 4 and 5). Exposing the layer of photosensitive material 112 comprises exposing the first region 106 of the first material layer 130 at a first focus level of the energy using the first region 126 of the lithography mask 120, and exposing the at least one second region 108 of the first material layer 130 at at least one second focus level of the energy using the at least one second region 128 of the lithography mask 120. The at least one second focus level is different than the first focus level, which is achieved by the first phase shift Φ₁ of the first region 126 and the at least one second phase shift Φ₂ of the at least one second region 128 of the mask 120.

Next, the layer of photosensitive material 112 is developed, forming patterns in the layer of photosensitive material 112, as shown in FIG. 7. The layer of photosensitive material 112 is then used as a mask while exposed portions of the material layer 130 are etched away, also shown in FIG. 7. The layer of photosensitive material 112 is then removed or stripped away from over the material layer 130, as shown in FIG. 8.

In some embodiments, the apertures 132 for features formed in the material layer 130 may comprise a minimum feature size or critical dimension (CD) of the lithography system or process used to pattern the apertures 132 for the features. Alternatively, the apertures in the material layer 130 may comprise dimensions larger than a minimum feature size, for example.

In a dual damascene process, a second lithography mask may be used to pattern additional feature apertures or trenches in an upper portion of the first material layer 130, as shown in phantom in FIG. 9 at 134, for example. The patterns may comprise trenches 134 for conductive lines disposed over the apertures 132 for vias which are formed in the entire thickness of the first material layer 130, as shown. Thus, the apertures 132 for vias are formed in a via-first dual damascene process, in this embodiment.

A second material layer 136 is formed over the first material layer 130, as shown in FIG. 9, filling the apertures 132 (and optionally also trenches 134, in a dual damascene process) formed in the first material layer 130. The second material layer 136 preferably comprises a different material than the first material layer 130, for example.

The second material layer 136 may comprise a conductive material in the embodiment shown, to form conductive features within the first material layer 130. The conductive material may comprise copper, a copper alloy, aluminum, an aluminum alloy, tungsten, a tungsten alloy, one or more liner or seed layers, or combinations thereof, as examples, although alternatively, the conductive material may comprise other materials.

Alternatively, the second material layer 136 may comprise an insulating material, a semiconductive material, a conductive material, or multiple layers or combinations thereof, for example. The second material layer 136 may comprise at least one liner, at least one seed layer, at least one metal, at least one semiconductive material, or combinations thereof, as examples, in some embodiments.

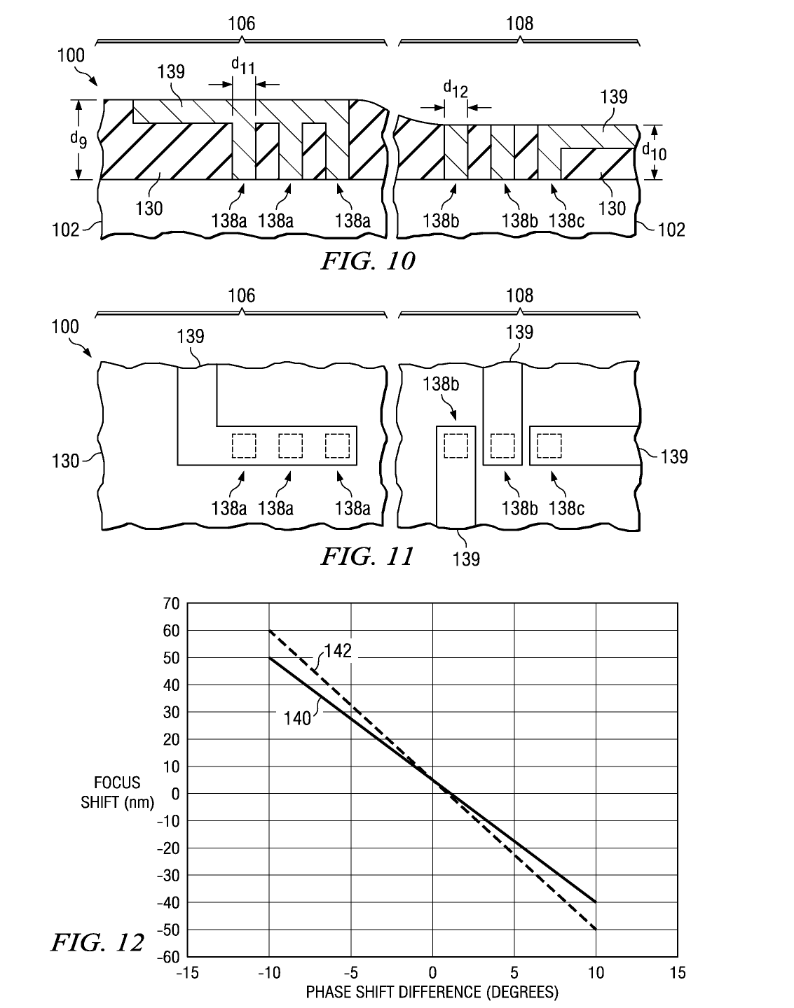

A CMP and/or etch process may be used to planarize the semiconductor device 100 top surface, e.g., the top surface 128 of the first material layer 130, removing excess portions of the second material layer 136 from over the top surface 128 of the first material layer 130 and forming features 138a, 138b, and 138c, as shown in FIG. 10, in a single damascene process. In a dual damascene process, conductive lines 139 are also formed in the top portion of the first material layer 130, wherein some of the conductive lines 139 may be connected to the vias 138a, 138b, and 138c. The vias 138a in the first region may comprise a dimension or width d₁₁ that is substantially the same as the dimension or width d₁₂ of vias 138b and 138c formed in the at least one second region 108 of the semiconductor device 100 in some embodiments.

FIG. 11 shows a top view of a semiconductor device 100 in FIG. 10 that has been patterned using a dual damascene process, simultaneously forming conductive lines 139 and vias 138a, 138b, and 138c within a first material layer 130 comprising an insulating material. The conductive lines 139 may comprise bends and may extend to other regions of the semiconductor device 100 to provide electrical connection for the semiconductor device 100, for example. One conductive line such as conductive line 139 in region 106 may be coupled to a plurality of vias 138a, as shown. Other conductive lines, such as conductive lines 129 shown in region 108 may be coupled to one via 138b or 138c.

FIG. 12 is a graph illustrating effects of phase shift difference on focus levels in regions 126 and 128, 226 and 228, and 326 and 338 of the lithography masks 120, 220, and 320 that have different phase shifts Φ₁ and Φ₂ in regions 126 and 128, 226 and 228, and 326 and 338 in accordance with embodiments of the present invention. Graphs 140 and 142 show phase shift difference impacts on focus shifts for two different sizes of contact holes or vias. The phase shift difference in degrees is shown on the x axis, and the focus shift in nm is shown on the y axis. The phase variation may be used to produce an optimal focus level or best focus for a region 106 or 108 of a semiconductor device 100. For example, a change in phase shift Φ₁ or Φ₂ by about 10 degrees results in a change the best focus level by about 50 nm or greater, depending on the size of the contact hole. The best focus level variation slope vs. phase shift difference is inversely proportional to the size of a contact hole or via, for example.

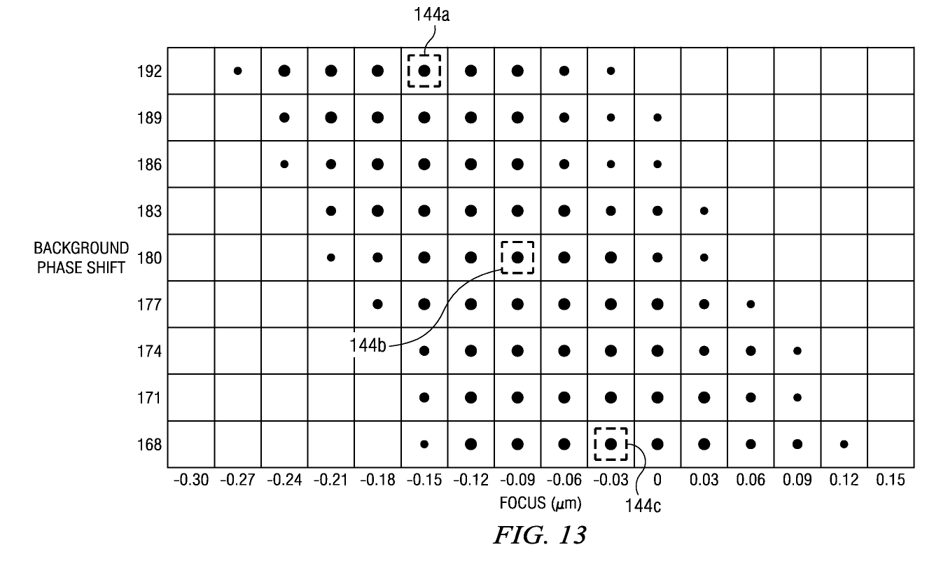

FIG. 13 is a plot illustrating differences in focus level created by the different phase shifts Φ₁ and Φ₂ (e.g., background phase shifts) in regions 126 and 128, 226 and 228, and 326 and 338 of the lithography masks 120, 220, and 320 described herein. The focus level is shown in μm on the x axis, and background phase shift Φ₁ and Φ₂ is shown in degrees on the y axis. Focus levels are plotted over a range of background phase shifts Φ₁ and Φ₂ with the best focus being shown in a central region of the plots of focus for each background phase shift Φ₁ and Φ₂. For example, the best focus is shown at 144a for a background phase Φ₁ or Φ₂ of 192 degrees, the best focus is shown at 144b for a background phase Φ₁ or Φ₂ of 180 degrees, and the best focus is shown at 144c for a background phase Φ₁ or Φ₂ of 168 degrees. The focus for the background phase shifts Φ₁ or Φ₂ to the left and right of the best focus 144a, 144b, and 144c points on the plot becomes worse at points farther away from the best focus 144a, 144b, and 144c points, for example.

The known or expected topography differences of a semiconductor device 100 may be used to determine a best focus for each topography dimension, and a background focus shift Φ₁ or Φ₂ may be determined to achieve the best focus for each topography dimension in regions 106 and 108 of a semiconductor device 100 in accordance with embodiments of the present invention.

Embodiments of the present invention provide novel methods of compensating for focus level differences between topographies across a surface of a semiconductor device 100, which can be predicted from upstream processes such as CMP processes and fill layer coatings. The varying focus levels are achieved by tuning the phase shift Φ₁ and/or Φ₂ of the lithography mask 120, 220, and 320 proximate or around the patterns for vias or other features on the masks 120, 220, 320, based on the simulated or expected topography of material layers below the vias or features.

The underlying material layer topography differences may be caused by varying circuit or feature densities, which may comprise a predictable uneven topography, e.g., after processing steps such as CMP processes. The topography unevenness may be simulated by correlating pattern density effects with the CMP process, for example. The topography information on the wafer may also obtained by measurements made by sensors in the lithography exposure tool, for example. The information obtained from the topography simulations or measurements may be used to create a lithography mask 120, 220, and 320 having the optimal phase shifts Φ₁ and Φ₂ for the topography measured, in accordance with embodiments of the present invention.

For example, if there is a low or decreased topography in a second region 108 of a semiconductor device 100, a phase shift Φ₂ of a second region 128, 228, or 328 of a lithography mask 120, 220, or 320 may be chosen that is less than about 180 degrees in order to achieve a best focus for features to be formed in the second region 108 of the semiconductor device 100, as an example.

Embodiments of the present invention include methods of manufacturing semiconductor devices 100 and semiconductor devices 100 manufactured using the methods described herein. Embodiments of the present invention include lithography masks 120, 220, and 320 including the varying phase shift regions 126, 128, 226, 228, 326, and 328, and lithography systems including and utilizing the novel lithography masks 120, 220, and 320 described herein. Embodiments of the present invention also include methods of fabricating the novel lithography masks 120, 220, and 320 described herein, for example.

Advantages of embodiments of the present invention include providing novel lithography masks 120, 220, and 320 and processes that utilize an effect of focus shift difference created by a phase shift Φ₁ and/or Φ₂ of a lithography mask 120, 220, or 320, e.g., caused by varying phase shifts Φ₁ and/or Φ₂ of the attenuated phase shift material 124, 224, or 324 or substrate 122, 222, or 322 of the mask 120, 220, or 320. A single mask 120, 220, or 320 and a single exposure process may be used to pattern features of a semiconductor device 100 that has an uneven topography, with a best focus level being achieved for all topographies of the semiconductor device 100.

A common depth of focus target for via layers is achievable in accordance with embodiments of the present invention. The variable phase shift attenuated phase shift masks 120, 220, or 320 described herein may be used to achieve a common focus for vias on varying topographies in a via first dual damascene scheme, for example.

Exposing the first region 106 of a material layer 130 at a first focus level of energy using a first region 126 of a lithography mask 120 and exposing a second region 108 of a material layer 130 at a second focus level of energy using a second region 128 of a lithography mask 120 may comprise achieving common depth of focus targets for vias 138a formed in the first region 106 of a workpiece 102 and vias 138b and 138c formed in the second region 108 of the workpiece 102, for example.

Alternatively, embodiments of the present invention described herein may be implemented in single damascene structures.

The novel methods, lithography masks 120, 220, or 320 and systems described herein are advantageously easily implemented into existing manufacturing process flows, lithography mask designs, and lithography tools and systems, with few additional processing steps being required for implementation of the invention, for example.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of manufacturing a semiconductor device, the method comprising:
providing a workpiece, the workpiece comprising a first thickness in a first region and at least one second thickness in at least one second region;
disposing a layer of photosensitive material over the workpiece;
providing a lithography mask, the lithography mask comprising a first phase shift in a first region and at least one second phase shift in at least one second region;
exposing the layer of photosensitive material to energy through the lithography mask;
developing the layer of photosensitive material, leaving portions of the workpiece exposed; and
affecting the exposed portions of the workpiece using the layer of photosensitive material as a mask.

2. The method according to claim 1, wherein the first phase shift of the first region of the lithography mask creates a first focus level in the first region of the workpiece when exposing the layer of photosensitive material to the energy through the lithography mask, and wherein the at least one second phase shift of the at least one second region of the lithography mask creates at least one second focus level in the at least one second region of the workpiece when exposing the layer of photosensitive material to energy through the lithography mask, the at least one second focus level being different than the first focus level.

3. The method according to claim 2, wherein the first focus level comprises an optimal focus level for forming at least one first feature in the first region of the workpiece, and wherein the at least one second focus level comprises an optimal focus level for forming at least one second feature in the at least one second region of the workpiece.

4. The method according to claim 1, wherein the at least one second thickness of the workpiece is different than the first thickness of the workpiece, the workpiece having an uneven topography, wherein disposing the photosensitive material over the workpiece comprises forming a conformal material, the conformal material having an uneven topography substantially similar to the uneven topography of the workpiece.

5. The method according to claim 1, wherein providing the workpiece comprises providing a workpiece having a material layer to be patterned disposed thereon, the material layer comprising a first thickness in the first region and at least one second thickness in the at least one second region, wherein affecting the exposed portions of the workpiece comprises affecting the material layer.

6. The method according to claim 5, wherein providing the workpiece comprises providing a workpiece wherein the material layer to be patterned disposed thereon comprises an insulating material, a conductive material, a semiconductive material, or multiple layers or combinations thereof.

7. The method according to claim 5, wherein providing the workpiece comprises providing a workpiece wherein the material layer comprises an insulating material disposed over a plurality of conductive features, the conductive features comprising nested features in the first region of the workpiece and isolated features in the at least one second region of the workpiece.

8. The method according to claim 1, wherein affecting the exposed portions of the workpiece comprises etching the exposed portions of the workpiece, implanting a substance into the exposed portions of the workpiece, or forming, depositing, or growing a material on the exposed portions of the workpiece.

9. A semiconductor device manufactured in accordance with the method of claim 1.

10. A method of manufacturing a semiconductor device, the method comprising:
providing a workpiece having a first material layer disposed thereon, the first material layer comprising a first thickness in a first region and at least one second thickness in at least one second region;
disposing a layer of photosensitive material over the first material layer;
providing a lithography mask, the lithography mask comprising a first phase shift in a first region and at least one second phase shift in at least one second region;
exposing the layer of photosensitive material to energy through the lithography mask, exposing the first region of the first material layer at a first focus level of the energy using the first region of the lithography mask and exposing the at least one second region of the first material layer at at least one second focus level of the energy using the at least one second region of the lithography mask;
developing the layer of photosensitive material; and
patterning the first material layer using the layer of photosensitive material as a mask.

11. The method according to claim 10, further comprising removing the layer of photosensitive material, and forming a second material layer over the patterned first material layer and exposed portions of the workpiece.

12. The method according to claim 11, further comprising planarizing the second material layer, removing the second material layer from over a top surface of the first material layer and leaving features formed from the second material layer within the first material layer.

13. The method according to claim 11, wherein providing the workpiece comprises providing the workpiece having a first material layer disposed thereon comprising an insulating material, wherein forming the second material layer comprises forming a conductive material, and wherein planarizing the conductive material comprises forming a plurality of vias within the insulating material.

14. The method according to claim 13, wherein exposing the first region of the first material layer at the first focus level of the energy using the first region of the lithography mask and exposing the at least one second region of the first material layer at the at least one second focus level of the energy using the at least one second region of the lithography mask comprises achieving common depth of focus targets for vias formed in the first region of the workpiece and vias formed in the at least one second region of the workpiece.

15. The method according to claim 10, wherein providing the lithography mask comprises providing a first lithography mask, wherein patterning the first material layer comprises patterning an entire thickness of the first material layer with a first pattern, further comprising:
removing the layer of photosensitive material;
patterning an upper portion of the first material layer with a second pattern using a second lithography mask; and
forming a second material layer over the patterned first material layer and the exposed portions of the workpiece.

16. The method according to claim 15, wherein providing the workpiece comprises providing the workpiece having a first material layer comprising an insulating material, wherein forming the second material layer comprises forming a conductive material, and wherein planarizing the conductive material comprises forming a plurality of vias in the first pattern within the insulating material and forming a plurality of conductive lines in the second pattern within the insulating material.

17. The method according to claim 10, wherein providing the workpiece comprises providing a workpiece having a plurality of nested features in the first region and a plurality of isolated features in one of the at least one second regions, wherein the first thickness of the first region is greater than the second thickness of the second region.

18. The method according to claim 17, wherein providing the workpiece having the plurality of nested features in the first region and the plurality of isolated features the second region comprises providing a workpiece wherein the plurality of nested features and the plurality of isolated features are formed in an insulating material layer, wherein the insulating material layer comprises an uneven topography on a top surface thereof.

19. A lithography mask, comprising:
a substrate; and
an attenuated phase shifting material disposed over the substrate, the attenuated phase shifting material comprising patterns in a first region and at least one second region of the lithography mask, the lithography mask comprising a first phase shift in the first region of the lithography mask and at least one second phase shift in the at least one second region of the lithography mask, the at least one second phase shift being different than the first phase shift, wherein when the lithography mask is used to pattern a layer of photosensitive material comprising an uneven topography, a first focus level is emitted from the lithography mask in the first region of the lithography mask and at least one second focus level is emitted from the lithography mask in the at least one second region of the lithography mask, the at least one second focus level being different than the first focus level.

20. The lithography mask according to claim 19, wherein the attenuated phase shifting material, the substrate, or both the attenuating phase shifting material and the substrate comprise a first thickness in the first region and at least one second thickness in the at least one second region, the at least one second thickness being different than the first thickness, or wherein the attenuated phase shifting material or the substrate, or both the attenuated phase shifting material and the substrate include an implanted substance adapted to produce the first phase shift or the at least one second phase shift of the lithography mask.

21. The lithography mask according to claim 20, wherein the at least one second thickness of the attenuated phase shifting material or the substrate being different than the first thickness of the attenuated phase shifting material or the substrate, and/or the implanted substance in the attenuated phase shifting material or the substrate, causes the at least one second focus level to be different than the first focus level.

22. The lithography mask according to claim 19, wherein the attenuated phase shifting material comprises a first thickness in the first region and at least one second thickness in the at least one second region, the at least one second thickness being different than the first thickness, wherein the first thickness and the at least one second thickness of the attenuated phase shifting material are determinable using Equation 1:
$$T / P S = \frac{λ}{n * 360} ; \qquad Eq . 1$$
wherein T comprises the first thickness or the at least one second thickness, wherein PS is the amount of phase shift in the first region or the at least one second region in degrees; wherein λ comprises a wavelength of an exposure process used to pattern a photosensitive material of a semiconductor device using the lithography mask; and wherein n comprises a refractive index of the attenuated phase shifting material of the lithography mask.

23. A lithography system including the lithography mask of claim 19, the lithography system comprising:
a support for a workpiece;
an energy source disposed proximate the lithography mask; and
a lens system disposed between the lithography mask and the support for the workpiece.

24. A method of fabricating a lithography mask, the method comprising:
providing a substrate, the substrate comprising a substantially transparent material;
forming an attenuated phase shifting material over the substrate;
patterning the attenuated phase shifting material with a pattern for a material layer of a semiconductor device; and
altering a thickness of a portion of the substrate or a portion of the attenuated phase shifting material in a first region or an at least one second region of the lithography mask, forming a first phase shift in the first region and at least one second phase shift in at least one second region, the at least one second phase shift being different than the first phase shift, wherein when the lithography mask is used to pattern a layer of photosensitive material comprising an uneven topography, a first focus level is emitted from the lithography mask in the first region of the lithography mask and at least one second focus level is emitted from the lithography mask in the at least one second region of the lithography mask, the at least one second focus level being different than the first focus level.

25. The method according to claim 24, wherein altering the thickness of the portion of the attenuated phase shifting material in the first region or the at least one second region comprises altering a transmissivity of the attenuated phase shifting material in the first region or the at least one second region, further comprising adjusting a size of the pattern for the material layer in the first region or the at least one second region of the lithography mask to compensate for the altered transmissivity.
